(19) United States
(12) Patent Application Publication
(10) Pub. No.: US 2008/0136686 A1
(43) Pub. Date: Jun. 12, 2008

(54) METHOD FOR THE SCALABLE CODING OF STEREO-SIGNALS

(75) Inventor: Bernhard Feiten, Berlin (DE)

Correspondence Address: DARBY & DARBY P.C., P.O. BOX 770, Church Street Station, New York, NY, 10008-0770, US

(73) Assignee: Deutsche Telekom AG, Bonn (DE)

(21) Appl. No.: 11/941,274

(22) Filed: Nov. 16, 2007

(30) Foreign Application Priority Data
Nov. 25, 2006 (DE) 10 2006 055 737.9

(51) Int. Cl. H03M 7/00

(52) U.S. Cl. 341/60

(57) ABSTRACT

Method for scalable coding of stereo signals includes left and right channel signals from a time into a frequency range; and then separately quantizing the transformed left and right channel signals; matrixing the quantized signals so as to form mid and side signals; and using the formed mid and side signals in a lossless coding stage so as to provide a coded signal for transmission.

### CROSS REFERENCE TO RELATED APPLICATIONS

This application claims benefit to German Patent Application No. 10 2006 055 737.9 filed Nov. 25, 2006.

### FIELD

The present invention relates to the coding of stereo signals and especially to the use of scalable coding methods.

### BACKGROUND

Scalable coding methods for the data compression of audio signals have the advantage that the transmission rate can be dynamically adapted to the properties of the networks and terminal devices. An advantageous aspect of this is the gradation of the bit rates into small increments by the coding method.

A stereo signal includes at least two channels, a left channel and a right channel. The similarity between the two channels is utilized for a data-reducing coding procedure. A method to transmit stereo signals is the mid/side method (Michael Dickreiter, Handbuch der Tonstudiotechnik [Manual of Sound Studio Technology], published by Saur Verlag, 1997]. In this process, the left and right channels are combined with each other in order to generate a mid channel and a side channel. The mid channel is formed from the sum of the right and left channels while the side channel consists of the difference between the left and right channels. Expressed as an equation, this means that

M=0.5(R+L)

S=0.5(R−L)

The factor of 0.5 is a common value in actual practice but it can also be selected differently. The recovery of the right and left channels is then done employing the relationship

R=M+S

L=M−S

If the left channel and the right channel are relatively similar to each other, a mid/side processing results in considerable savings in terms of the bit volume needed for the coding since the side channel then has relatively less energy than the left or right channels and far fewer bits are needed to code the side channel. In borderline cases in which the left channel and the right channel are identical, the mid channel will be equal to the left channel or equal to the right channel, while the side channel will be 0. The more similar the left and right channels are, the lower the energy of the side channel will be and thus the fewer bits are needed to code the side channel. If the left and right channels are less similar, the bit efficiency drops accordingly in the case of a mid/side coding.

Stereo signals are usually coded with methods that process the audio signals in the spectral range. First of all, the left and right channels of the audio signal—which as a rule are present in the form of PCM (pulse code modulation) sampled values—are converted from the time range into the frequency range. For this transformation, modern coding methods make use, for instance, of the so-called modified discrete cosine transform (MDCT) in order to obtain a block-wise frequency representation of an audio signal. The stream of time-discrete sampled audio values is windowed in order to yield a windowed block of sampled audio values that are then converted into a spectral representation by a transform. For each time window, a corresponding number of spectral coefficients is obtained. The transform divides the frequency spectrum into a certain number of frequency bands (sub-bands) of the same width. The number of transformation points and the sampling rate determine the bandwidth of the sub-bands. These sub-bands are compiled in groups on the basis of acoustical properties. At low frequencies, there are only a few sub-bands in a group, whereas there are many at high frequencies. A scaling factor is determined for each group. The spectral coefficients are then quantized relative to these scaling factors. During the coding procedure, bits are allocated to the scaling factors and to the transform coefficients in accordance with the target bit rate. In this context, the bit allocation is done in such a way that the errors that occur are as imperceptible as possible. The scaling factors are also transmitted and are needed so that the decoder can reconstruct the original signal from the transmitted bits.

With mid/side coding, after the transformation into the frequency range by MDCT, the signals of the left and right channels undergo a matrixing for purposes of summation and difference formation. The mid and side signals thus formed are subsequently quantized. The quantization is a lossy coding procedure since quantization errors occur due to the process. As a result of the quantization errors, the signals can no longer be precisely reconstructed after the transmission, giving rise to an unnatural stereo image.

In addition to the data-reducing effect of the mid/side coding, it also has the effect that, when the left and right channels are very similar, the quantization error in the left channel and in the right channel is correlated with the quantization error of the other channel, so that the quantization error also occurs in the middle, where it is masked by the useful signal somewhat or considerably better than in the uncorrelated case. However, as soon as the left and right channels are relatively dissimilar, owing to the stereo effect, the useful signal will be either left or right, while the quantization error is correlated and comes to lie more in the middle.

In order to attain a further data volume reduction by the coding, the quantized mid/side signals are subsequently entropy encoded by Huffman coding with an eye towards achieving lossless coding. By adding other information such as, for example, scaling factors, a bit stream is formed from the quantized and entropy encoded mid/side signals by a bit stream multiplexer, and this bit stream can then be transmitted.

Scalable coding methods are advantageous for stereo signals (J. Li, Embedded Audio Coding (EAC) With Implicit Auditory Masking; ACM Multimedia 2002). Scalable coding methods are configured in such a way that the bit stream on the output side has at least a first and a second scaling layer. The first scaling layer can differ from the second scaling layer or from any desired number of scaling layers in the audio coding method itself, in the audio bandwidth, in the audio quality regarding mono/stereo or in a combination of the mentioned quality criteria.

Scalable audio encoders for multi-channel stereo transmission are often configured in such a way that the mono signal, that is to say, the mid signal, is used for the first scaling layer, while the side channel is embedded into the other scaling layers. A decoder that is just configured in a simple manner will only derive the first scaling layer from the scaled bit stream and then deliver a mono signal. A decoder for stereo reproduction employs, in addition to the mid layer, also the side layer, in order to deliver a stereo signal having the full bandwidth.

A scalable encoder for stereo signals that uses the mid signal as the first scaling layer and the side signal in the other scaling layers exhibits its best overall efficiency when there is a high degree of similarity between the left channel and the right channel. In the case of stereo channels that do not correlate with each other or in the case of sudden changes in the properties of both channels with respect to each other, the efficiency of a mid/side coding decreases.

The process of decoding a mid/side transmission is such that the received bit stream is divided by a demultiplexer into coded quantized mid/side signals and into additional information. The entropy encoded quantized mid/side signals are first entropy decoded in order to obtain the quantized mid/side signals that are then inversely quantized. The decoded mid/side signals have quantization errors that were brought in during the coding, as a result of which the signals that have been converted into the time representation by a synthesis filter bank after the de-matrixing cannot be reconstructed to the original conditions.

### SUMMARY

An aspect of the present invention includes using scalable coding according to the mid/side method so that the quantization errors are better masked and stereo imaging errors are minimized during the spatial reproduction.

In an embodiment, the present invention provides a method for scalable coding of stereosignals which includes transforming left and right channel signals from a time into a frequency range; and then separately quantizing the transformed left and right channel signals; matrixing the quantized signals so as to form mid and side signals; and using the formed mid and side signals in a lossless coding stage so as to provide a coded signal for transmission.

### BRIEF DESCRIPTION OF THE DRAWINGS

Aspects of the present invention will now be described by way of exemplary embodiments with reference to the following drawing, in which:

FIG. 1 shows an encoder and decoder according to an exemplary embodiment of the present invention.

### DETAILED DESCRIPTION

During the process of coding, the left channel as well as the right channel are transformed and quantized and the mid/side processing only takes place after the quantization. Therefore, the summation and difference formation are carried out with the already quantized signals of the left and right channels.

The effect of the quantization error can be reduced during the mid/side matrixing if the matrixing is carried out after the quantization. This can be shown with reference to the transmission equations.

The mid signal is formed by the addition of the left and right channels, whereby the side signal results from the difference.

M=0.5R+0.5L

S=0.5R−0.5L (1)

The recovery of the right and left channels is done with the operations:

R=M+S

L=M−S (2)

The quantization procedure is described by the quantization function

y=Q(x) (3)

The following transmission equations result for the conventional coding, making use of the quantization for the mid/side signals (M/S quantization):

R′=Q(0.5R+0.5L)+Q(0.5R−0.5L)

L′=Q(0.5R+0.5L)−Q(0.5R−0.5L) (4)

If only the mono signal is employed for the decoding, the following results:

R′=Q(0.5R+0.5L)

L′=Q(0.5R+0.5L)

The inventive optimization of the mid/side stereophony employing the quantization for the signals of the right and left channels (R/L quantization) is as follows. The sum and difference signals are formed from the quantized R/L signals:

M=0.5Q(R)+0.5Q(L)

S=0.5Q(R)−0.5Q(L)

Using equation (2) then yields the following:

R′=0.5Q(R)+0.5Q(L)+0.5Q(R)−0.5Q(L)

L′=0.5Q(R)+0.5Q(L)+0.5Q(R)−0.5Q(L)

The following then results for the optimization:

R′=Q(R)

L′=Q(L) (5)

If only the mono signal is employed for the decoding, the following results:

R′=0.5Q(R)+0.5Q(L)

L′=0.5Q(R)+0.5Q(L)

In order to evaluate the influence of the occurring quantization error, an actuation of the system with stereo signals having the following form is considered:

Xr=αX

X1=(1−α)X (6)

Only the left channel is modulated for α=0, while the left and right channels are both modulated for α=0.5, and only the right channel is modulated for α=1.

For the conventional transmission using the M/S quantization, the following output signals are obtained for the input signals according to equation (4):

Xr′=Q(0.5X)+Q(αX−0.5X)

X1′=Q(0.5X)−Q(αX−0.5X) (7)

Accordingly, the following output signals are obtained for the optimization according to the invention employing the R/L quantization:

Xr′=Q(αX)

X1′=Q((1−α)X) (8)

With a value of α=0.5, the results for the output signals are identical in both representations. In actual practice, however, it is normally the case that a takes on any value between 0 and 1. Critical situations occur when a approaches the limits 0 or 1. Then, one of the channels is strongly modulated by the source signal while the other channel is weakly modulated.

In order to represent the quantization error, a quantizer having a quantization interval with the magnitude D is assumed. The quantization error is designated with d and can then take on the values −D/2<d<D/2.

For the conventional use of the M/S quantization, equation (7) yields the following:

Xr′=0.5X+dm+(αX−0.5X+ds)

X1′=0.5X+dm−(αX−0.5X+ds) (9)

The quantization error of the mid signal is dm, that of the side signal is ds. A random relationship exists between dm and ds. The quantization error in the M/S quantization can take on values between −D and +D in the sum.

The following then results for the output signals in the case of actuation with, for example,

α=0

Xr′=dm+ds

X1′=X+dm−ds (9a)

and for

α=0.5

Xr′=0.5X+dm+ds

X1′=0.5X+dm−ds (9b)

With α=0, a quantization error is audible in the right channel, although only the left channel has the signal. In the case of α=0.5, it can be seen that the quantization error occurs with an in-phase and an out-of-phase component. This causes the quantization error to become audible with a large stereo effect.

The following relationships result on the basis of equation (8) for the optimization according to the invention employing the R/L quantization:

Xr′=αX+dr

X1′=(1−α)X+dl (10)

dr is the quantization error for the right channel, dl is the quantization error for the left channel. For a quantization interval having the magnitude D, the quantization error d can assume the values −D/2<d<D/2 as already mentioned. The quantization errors do not undergo summation in the R/L quantization. Therefore, the error remains within the range −D/2<d<D/2.

For the output signals, the following is obtained for

α=0

Xr′=dr

X1′=X+dl (10a)

and for

α=0.5

Xr′=0.5X+dr

X1′=0.5X+dl (10b)

In comparison to the conventional M/S quantization, with the R/L quantization only one quantization error is possible that is at the maximum half as large and does not have any out-of-phase components so that the useful signal masks the quantization error much more effectively.

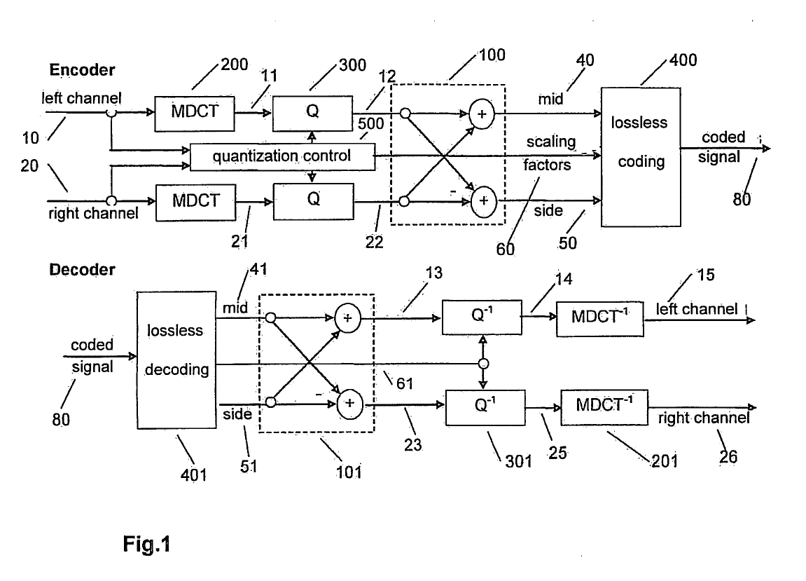

FIG. 1 shows encoders and decoders as an example of the use of the inventive principle of a mid/side formation after the quantization of the signals of the left and right channels. The description is limited to a two-channel transmission and coding. However, the same principles can also be used well for multi-channel transmission and coding.

The left (10) and right (20) channels of an audio signal are first transformed from the time range into the frequency range. To this end, the principle of the variable modified cosine transform (200) is employed for both audio channels. The spectral values of the left (11) and right (12) channels are quantized in the next step. The quantizer (300) is controlled by quantization control (500). The quantization can be assisted by a division into frequency bands. This division has the advantage that the quantization error is adapted to the spectral properties of the useful signal, as a result of which they cannot be perceived as quickly by our sense of hearing. In this process, the quantization is adapted to the modulation in the appertaining frequency band in that a scaling factor is determined for each band. The quantization control uses the left (10) and right (20) input channels to determine the scaling factors. A special aspect of the quantization control in the present coding method is that the same scaling factor is used for the left and right channels in order to allow the summation and difference formation in a linear numerical set. Aside from this constraint, several methods can be used to determine the optimal scaling factors (Marina Bosi and Karlheinz Brandenburg, Introduction to Digital Audio Coding and Standards, published by Springer Verlag 2002). The quantization fulfills the function of a lossy reduction of the bits needed for the coding.

The spectrally broken down and quantized left (12) and right (22) channels are then fed to a mid/side transform stage (100) in order to convert the left/right signals into mid/side signals. Further data reduction takes place in another stage for lossless coding (400). The mid (40) and side (50) signals as well as the scaling factors (60) are fed to this stage, which can be realized, for example, by Huffman coding. The result is the coded signal (80).

The coded signal (80) is decoded by executing the steps in the reverse order. The lossless decoding reconstructs the mid (41) and side (51) signals as well as the scaling factors (61). In the next stage (101), the mid and side signals are transformed back into left (13) and right (23) quantized signals. The scaling factors (61) are then employed to perform the inverse quantization (301) in order to produce the original values of the spectral coefficients. The spectrally broken down left (14) and right (15) signals are reset to the reconstructed signals for the left (15) and right (25) channels by the inverse modified discrete cosine transform (201).

By minimizing the quantization errors it is possible to generate the bit stream more flexibly in actual practice. The magnitude (bit rate) of the coded signal (80) can be scaled. The bit stream contains the scaling factors, the mid signal and the side signal. The bit rate can now be reduced in different ways. First of all, high-frequency portions of the side signal can be left out. Then, for instance, the high-frequency portions of the mid signal can be left out. Then, the unutilized scaling factors do not need to be transmitted either. In the next step, the low-frequency portions of the side signal could be reduced until, for example, the side signal is no longer present at all in the bit stream. The quality of the stereo transmission can thus be converted step by step into a mono transmission as the spectral bandwidth decreases.

1-3. (canceled)

4. A method for scalable coding of stereo signals, comprising:
transforming left and right channel signals from a time into a frequency range;
and then separately quantizing the transformed left and right channel signals;
matrixing the quantized signals so as to form mid and side signals; and
using the formed mid and side signals in a lossless coding stage so as to provide a coded signal for transmission.

5. The method according to claim 4, wherein the quantizing includes diving the transferred signals into frequency bands, determining a scaling factor for each frequency bands from the left and right channels by a quantization control, the scaling factors for the left and right channels being the same, and further comprising-transmitting the scaling factors in the coded signal together with the mid and side signals.

6. The method according to claim 4, wherein a bit stream of the coded signal is configurable flexibly such that a bit rate is incrementally adaptable to transmission conditions.

7. The method according to claim 5, wherein a bit stream of the coded signal is configurable flexibly such that a bit rate is incrementally adaptable to transmission conditions.
